(19) United States
(12) Patent Application Publication
(10) Pub. No.: US 2002/0056909 A1
(43) Pub. Date: May 16, 2002

(54) SEMICONDUCTOR CHIP PACKAGE AND METHOD OF FABRICATING THE SAME

(76) Inventors: HEUNG-KYU KWON, SEONGNAM (KR); MIN-KYO CHO, SEOUL (KR)

Correspondence Address: SKJERVEN MORRILL MACPHERSON LLP, 25 METRO DRIVE, SUITE 700, SAN JOSE, CA, 95110, US

(21) Appl. No.: 09/464,322

(22) Filed: Dec. 15, 1999

(30) Foreign Application Priority Data
Dec. 15, 1998 (KR) 1998-54972

(51) Int. Cl. H01L 23/34

(52) U.S. Cl. 257/720; 257/678; 257/706; 257/707; 257/778

(57) ABSTRACT

The present invention is directed to a semiconductor chip package that can effectively remove heat from a semiconductor chip, and a method of fabricating the package. In accordance with an embodiment of the invention, the package includes: a substrate having bonding pads; a semiconductor chip having conductive bumps on the front side thereof, the conductive bump contacting the bonding pads; a heat slug bonded to the backside of the semiconductor chip; and a solder film which makes the bonding between the heat slug and the backside of the semiconductor chip. The heat slug can be shaped such that a portion of the heat slug is attached to the substrate by an adhesive. The method includes: preparing a semiconductor chip having conductive bumps on the front surface of the semiconductor chip; bonding a heat slug on the backside of the semiconductor chip using a solder film; and attaching the semiconductor chip on the substrate such that the conductive bumps of the semiconductor chip contacts bonding pads of the substrate.

### BACKGROUND OF THE INVENTION

1. Field of the Invention

The present invention relates to a semiconductor chip package and a method of fabricating the same and, more particularly, to a flip chip package having good heat dissipation capability.

2. Description of the Related Art

As a chip interconnection method, flip-chip technology has a number of advantages over other chip interconnection methods such as wirebonding. For example, a flip-chip package can accommodate more is external connection terminals than conventional packages using wirebonding. In addition, the flip-chip technology can enhance the electrical and thermal characteristics of semiconductor devices. Accordingly, newly developed semiconductor devices often connect to an external component using flip-chip interconnection.

For the enhancement of the thermal characteristics, flip-chip packages, in which the active face of the semiconductor chip connects to a substrate via solder or gold bumps, employ a heat sink attached to the back side of the semiconductor chip. The methods of forming the bumps are well-known in the art. Examples of the methods are described in U.S. Pat. Nos. 4,950,623 and 5,162,257, which are incorporated herein by references in their entireties. Typically, the heat sink is attached by an epoxy adhesive, which forms an adhesive layer between the heat sink and the semiconductor chip. For effective heat dissipation from the semiconductor chip through the heat sink, the adhesive layer should be as thin as possible because the heat conductivity of the adhesive layer is inferior to that of the metal heat sink.

Alternatively, the heat sink is clamped with the substrate so that the heat sink contacts the back side of the semiconductor chip without the adhesive layer. However, in this case, excessive clamping force may damage the semiconductor chip.

### SUMMARY OF THE INVENTION

The present invention is directed to a semiconductor chip package that can effectively remove the heat from a semiconductor chip, and a method of fabricating the package. In accordance with an embodiment of the invention, the package includes: a substrate having bonding pads; a semiconductor chip having conductive bumps on the front side thereof, the conductive bumps contacting the bonding pads; a heat slug bonded to the backside of the semiconductor chip; and a solder film which makes the bonding between the heat slug and the backside of the semiconductor chip. The heat slug can be shaped such that a portion of the heat slug is attached to the substrate by an adhesive, and the heat slug also can have throughholes.

The backside of the semiconductor chip includes a metal layer for strengthening the adhesion between the semiconductor chip and the solder film. The heat slug includes an adhesion layer formed on a surface of the heat slug that contacts the solder film. In addition, the space between the semiconductor chip and the substrate is filled with an underfilling material.

A method for manufacturing a semiconductor chip package in accordance with an embodiment of the invention includes: preparing a semiconductor chip having conductive bumps on a front surface of the semiconductor surface; bonding a heat slug on the backside of the semiconductor chip using a solder film; and attaching the semiconductor chip on a substrate such that the conductive bumps of the semiconductor chip contacts bonding pads of the substrate.

### BRIEF DESCRIPTION OF THE DRAWINGS

The features and advantages of the present invention will become more apparent by describing in detail embodiments thereof with reference to the attached drawings in which:

FIG. 1 is a perspective view of a semiconductor package according to an embodiment of the present invention;

FIG. 2 is a partial perspective view that shows an enlargement of part of the semiconductor package of FIG. 1;

FIG. 3 is a perspective view of a semiconductor package according to another embodiment of the present invention;

FIGS. 4A to 4C are sectional views illustrating the steps of fabricating the semiconductor package of FIG. 1; and

FIGS. 5A to 5B are sectional views illustrating the steps of fabricating the semiconductor package of FIG. 3.

Use of the same reference symbols indicates similar or identical items.

### DETAILED DESCRIPTION OF THE INVENTION

The present invention is directed to semiconductor packages that can effectively dissipate heat from a semiconductor chip, and methods of fabricating the semiconductor packages.

FIG. 1 shows a semiconductor package 100 in accordance with an embodiment of the present invention. In the semiconductor package 100, a semiconductor chip 10, which has conductive bumps 16 on an active surface of chip 10, is on a substrate 20, such that the conductive bumps 16 connect to bonding pads 22 formed on the substrate 20. The substrate 20 further includes external terminals 21 for electrically connecting the semiconductor chip 100 to an external component. The bonding pads 22 electrically connect to respective external terminals 21 through a circuit pattern (not shown) formed, for examlpe, in the substrate 20. The external terminals 21 can have various forms, such as straight leads, gull-wing type leads, and solder balls. As an example, the external terminals 21 of FIG. 1 are straight leads.

Between the chip 10 and the substrate 20, an under-filling portion 50 is formed to prevent cracking of the conductive bumps 16 due to the thermal expansion mismatch between the chip 10 and the substrate 20. Then, in order to promote the heat dissipation from the chip 10, a plate-shaped heat slug 40 is attached on the backside of the chip 10, on which an adhesion layer 14 is formed, using a solder film 30. The heat slug 40 is formed of a metal such as Cu, Al or CuW. In addition, grooves 43 are formed on the heat slug 40 to facilitate the heat dissipation by increasing the surface area of the heat slug 40. In addition, an adhesion layer (not shown), which is typically a Ni/Al, Ag, or Pd layer, can be formed on one side 41 of heat slug 40 contacting the solder film 30 to secure the bonding between the heat slug 40 and the conductive solder film 30, and an anodizing layer (not shown) is formed on the other side of the heat slug 40 to prevent oxidation of the heat slug 40. The solder film 30 is formed of a metal alloy which includes Pb, Sn, Ag, In and/or Bi. Such metal alloy typically has thermal conductivity of 25W/mK to 40W/mK and good adhesion strength. The solder film 30 preferably has a size equal to or greater than that of the semiconductor chip 10, so that the solder film 30 covers the whole backside of the chip 20. The layer 14, which promotes the adhesion between the semiconductor chip 10 and the solder film 30, typically has a multi-layer metal structure. Exemplary structures of the layer 14 include VNi/Au, Ti/VNi/Au, Cr/VNi/Au, Ti/Pt/Au, Cr/CrCu/(Cu)/Au, TiW/(Cu, NiV)/Au, VNi/Pd, Ti/VNi/Pd, Cr/VNi/Pd, Ti/Pt/Pd, Cr/CrCu/(Cu)/Pd, and TiW/(Cu, NiV)/Pd.

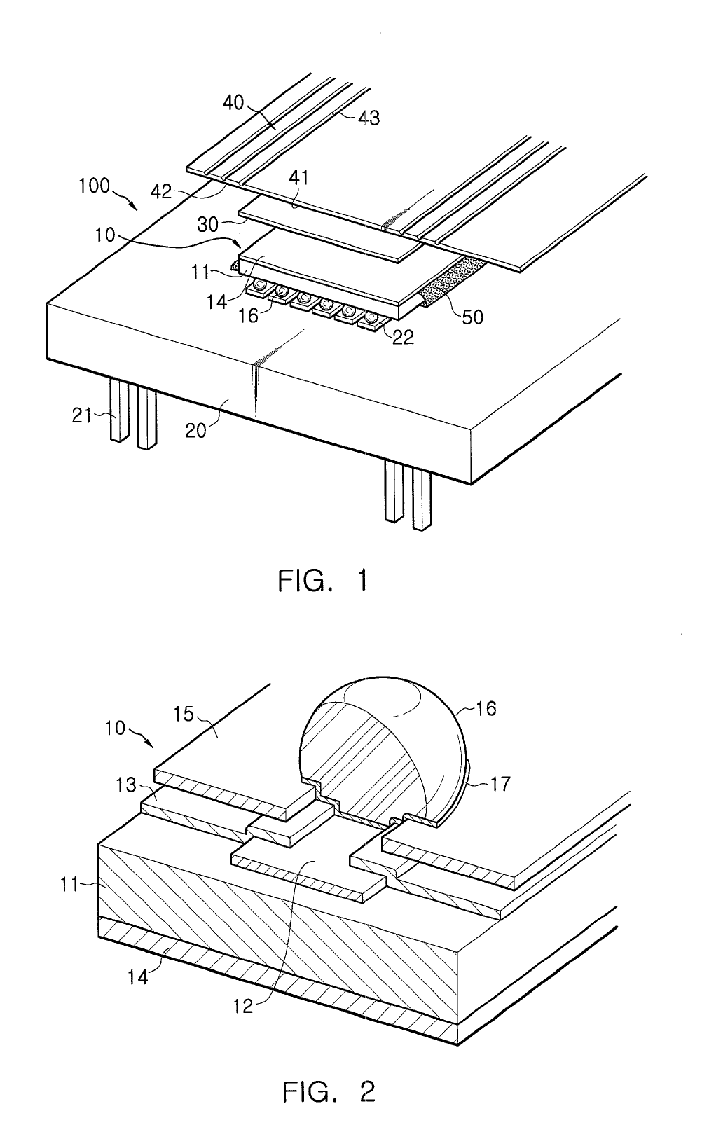

FIG. 2 show the structure of the semiconductor chip 10 of FIG. 1 around the conductive bump 16. On a silicon substrate 11, a chip pad metal 12 is formed, and a passivation layer 13 and a polyimide layer 15 are sequentially formed on silicon substrate 11 such that an opening in the passivation layer 13 and the polyimide layer 15 exposes a portion of the chip pad metal 12. Then, an under-bump metallurgy film 17 is formed on the exposed chip pad metal 12, and the conductive bump 16 is formed on the under-bump metallurgy film 17. The under-bump metallurgy film 17 typically includes Cr, Cr/Cu and/or Cu layers.

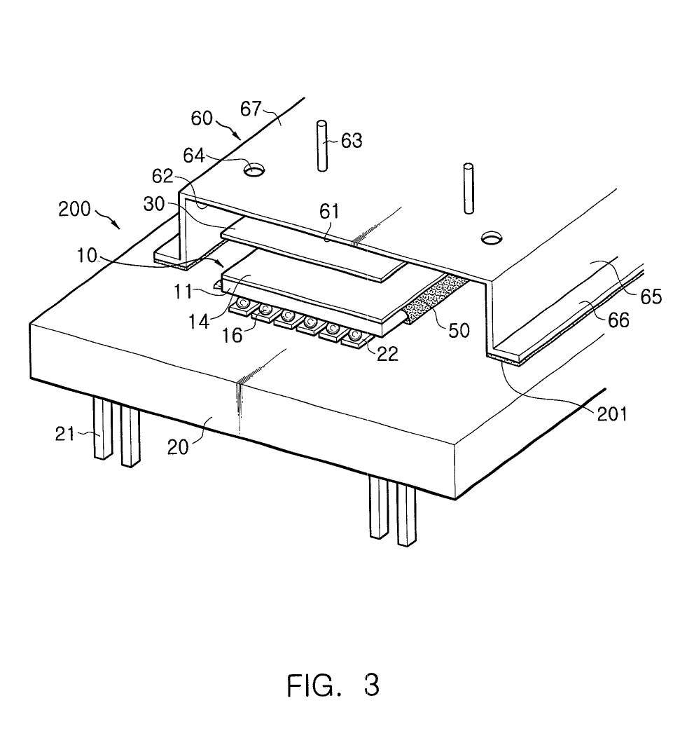

FIG. 3 shows a semiconductor package 200 according to another embodiment of the present invention. The semiconductor package 200 has the same structure as the semiconductor package 100 of FIG. 1 except that a heat slug 60 replaces the heat slug 40. Accordingly, only the heat slug 60 will be explained.

As shown in FIG. 3, the heat slug 60 includes a top portion 67, side standing portions 65 bent from the top portion 67, and side end portions 66 bent again from the side standing portions 65. The top portion 67 of the heat slug 60 contacts the conductive solder film 30 like the heat slug 40 of FIG. 1, and the side end portions 66 of the heat slug 60 are attached to the substrate 20 via a shock-absorbing adhesive layer 201, so that the heat slug 60 covers the chip 10. The adhesive layer 201 may include silicon rubber particles to absorb the thermo-mechanical stress between the heat slug 60 and the substrate. The heat slug 60 can further includes cooling pins 63 formed on the top portion 67 to improve heat dissipation, and gas holes 64 through which the gas generated during the manufacturing of the semiconductor package 200 can flow. The gas holes 64 can be formed on the top and/or side standing portions 65 of the heat slug 60. The formation positions of the processing gas inlet holes 64 can be selectively changed in accordance with the circumstances of the work line.

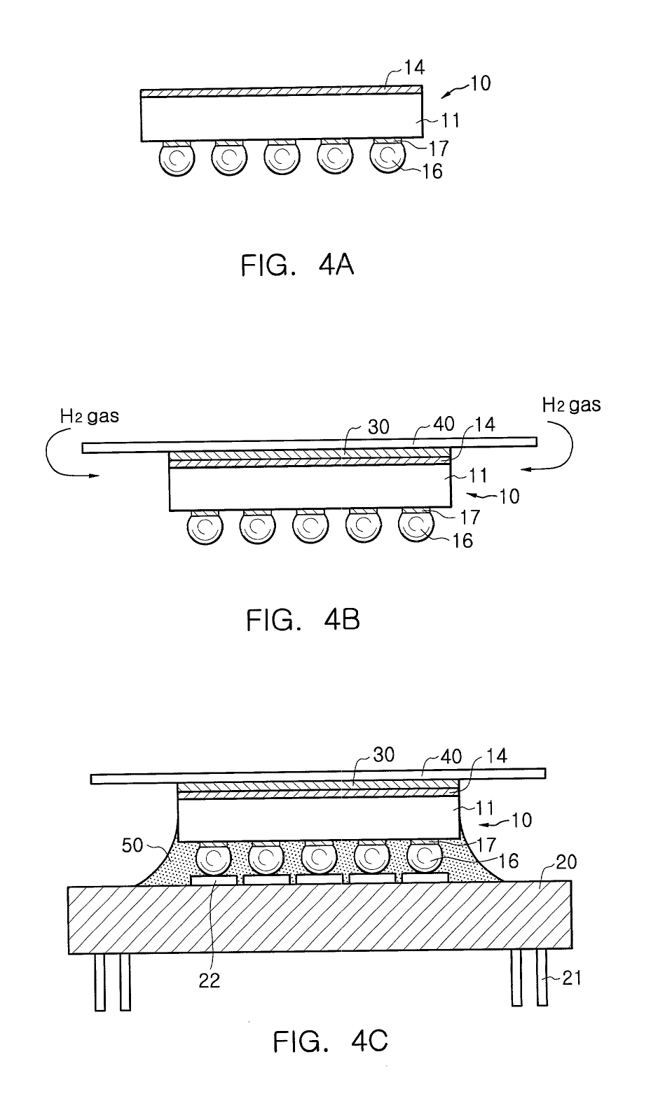

FIGS. 4A to 4C illustrate a method of fabricating the semiconductor package 100 of FIG. 1. The method includes: preparation of the semiconductor chip 10 having conductive bumps 16 (FIG. 4A); bonding of the heat slug 40 to the semiconductor chip 10 (FIG. 4B); and bonding of the semiconductor chip 10 to the substrate 20 (FIG. 4C).

In preparing the semiconductor chip 10 of FIG. 4A, the under-bump metallurgy (UBM) layer 17, which includes Cr, Cr/Cu, and Cu layers, is formed on the chip pads (not shown) of the semiconductor substrate 11, in and on which circuits (not shown) have been formed, by known sputtering and patterning. Typically, the semiconductor substrate 11 is a silicon wafer. On the patterned UBM layer 17, under which the chip pads are, the conductive bumps 16 are formed. Then, the metal layer 14 is formed on the backside of the semiconductor substrate 11 by sputtering, evaporation, electro-plating, or electroless-plating. As previously described, the metal layer 14 is formed of a multi-layer metal film such as VNi/Au, Ti/VNi/Au, Cr/VNi/Au, Ti/Pt/Au, Cr/CrCu/(Cu)/Au, TiW/(Cu, NiV)/Au, VNi/Pd, Ti/VNi/Pd, Cr/VNi/Pd, Ti/Pt/Pd, Cr/CrCu/((Cu)/Pd, or TiW/(Cu, NiV)/Pd.

Before the forming of the metal layer 14, the backside of the semiconductor substrate 11 can be chemically cleaned using an HF solution to strengthen the bonding between the semiconductor substrate 11 and the metal layer 14. The cleaning process can be carried out by plasma cleaning.

The formation of the UBM layer 17 and the conductive bump 16, and the formation of the metal layer 14 can be performed in a reverse order. After the formation of UBM layer 17, the conductive bump 16, and the metal layer 14, the semiconductor substrate in a wafer form is divided into multiple pieces of semiconductor chips 10 by sawing process.

Regarding to FIG. 4B, in order to attach the heat slug 40 to the backside of the semiconductor chip 10, a bonding apparatus (not shown) aligns the heat slug 40 and the solder film 30 on the backside of the semiconductor chip 10, and applies heat to the aligned elements under H₂ environment. The heat application medium can be a furnace or a thermode pressing the heat slug 40 from the top.

Regarding to FIG. 4C, the semiconductor chip 10 with the heat slug 40 attached thereon is attached to the substrate 20. The semiconductor chip 10 is placed on the substrate 20 with the conductive bumps 16 of the semiconductor chip 10 on respective bonding pads of the substrate 20. Then, heating in a reflow furnace attaches the semiconductor chip 10 to the substrate 20. Alternatively, an adhesive layer (not shown), which bonds the conductive bumps 17 to the respective bonding pads 22, attaches the semiconductor chip 10 to the substrate 20. After the bonding between the conductive bumps 17 and the respective bonding pads 22, liquid resin is injected into the space between the semiconductor chip 10 and the substrate 20 to form the under-filling portion 50. Accordingly, the semiconductor package 100 has been completed.

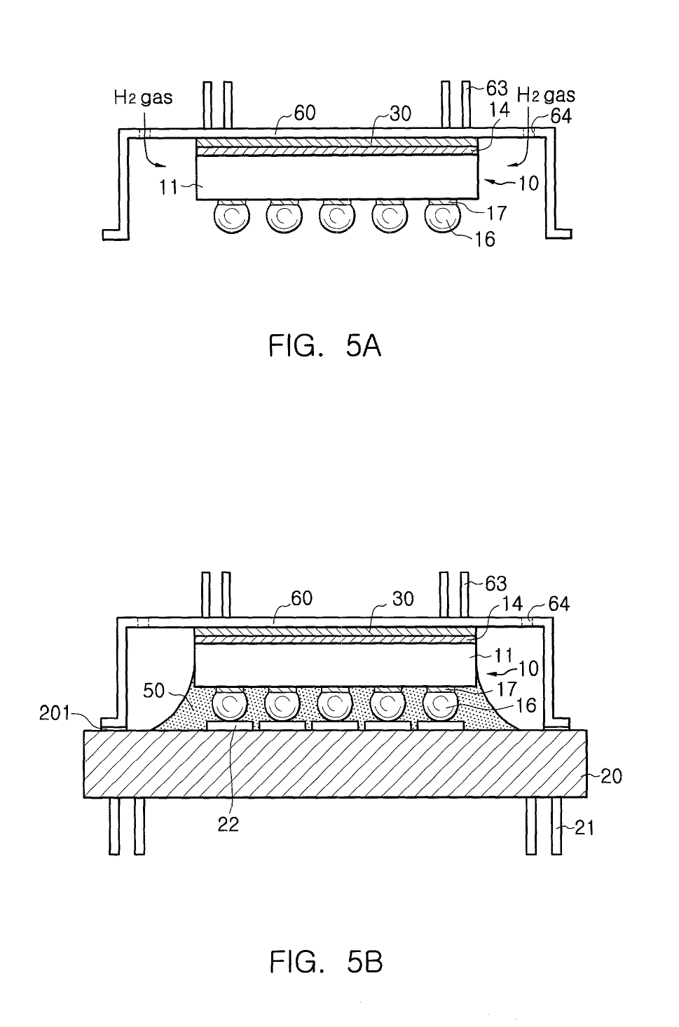

FIGS. 5A to 5C illustrate a method of fabricating the semiconductor package 200 of FIG. 3. The assembly of the semiconductor package 200 is similar to that of the semiconductor package 100.

The semiconductor chip 10 is prepared as described with reference to FIG. 4A. Then, as shown in FIG. 5A, the heat slug 60 is attached to the semiconductor chip 10 in the same way that the heat slug 40 of FIG. 4B is attached. FIG. 5B illustrates the bonding between the semiconductor chip 10 and the substrate 20, which is similar to the bonding described in regard to FIG. 4C except for the formation of the adhesive layer 201. Adhesive is applied on the substrate 20 to form the adhesive layer 201 before the semiconductor chip 10 with the heat slug 60 is placed on the substrate 20, so that the adhesive layer 201 bonds the heat slug 60 to the substrate 20.

The semiconductor package according to the present invention includes a heat slug and uses a solder film to attach the heat slug to a semiconductor chip. Since no polymer adhesive, which may retard heat dissipation, is between the chip and the heat slug, the heat generated from the chip can be effectively removed through the heat slug.

While the present invention has been described in detail with reference to the specific embodiments, those skilled in the art will appreciate that various modifications and substitutions can be made thereto without departing from the spirit and scope of the present invention as set forth in the appended claims.

What is claimed is:

1. A semiconductor chip package comprising:
a substrate having a plurality of bonding pads;
a semiconductor chip having a plurality of conductive bumps on a front side thereof, the conductive bumps contacting the bonding pads;
a heat slug bonded to a backside of the semiconductor chip; and
a solder film that bonds the heat slug to the backside of the semiconductor chip.

2. The semiconductor chip package of claim 1, wherein the solder film includes one selected from a group consisting of Pb, Sn, Ag, In, and Bi.

3. The semiconductor chip package of claim 1 wherein the backside of the semiconductor chip includes a metal layer formed thereon for strengthening the adhesion between the semiconductor chip and the metal film.

4. The semiconductor chip package of claim 3 wherein the metal layer is a multi-layered film selected from a group consisting of VNi/Au, Ti/VNi/Au, Cr/VNi/Au, Ti/Pt/Au, Cr/CrCu/(Cu)/Au, TiW/(Cu, NiV)/Au, VNi/Pd, Ti/VNi/Pd, Cr/VNi/Pd, Ti/Pt/Pd, Cr/CrCu/(Cu)/Pd and TiW/(Cu, NiV)/Pd.

5. The semiconductor chip package of claim 1, wherein a space between the semiconductor chip and the substrate is filled with an underfilling material.

6. The semiconductor chip package of claim 1, wherein the solder film has a size equal to or lager than a size of the semiconductor chip.

7. The semiconductor chip package of claim 1, wherein the heat slug is formed of a material selected from a group consisting of Cu, Al, and CuW.

8. The semiconductor chip package of claim 1, wherein the heat slug comprises an adhesion layer formed on a surface of the heat slug that contacts the solder film.

9. The semiconductor chip package of claim 8, wherein the adhesion layer is a layer selected from a group consisting of a Ni/Au layer, a Ag layer, and a Pd layer.

10. The semiconductor chip package of claim 1, wherein the heat slug is coated with an anodizing layer.

11. The semiconductor chip package of claim 1, wherein the heat slug is shaped such that a portion of the heat slug is attached to the substrate by an adhesive.

12. The semiconductor chip package of claim 11, wherein the adhesive includes silicon rubber or elastomer.

13. The semiconductor chip package of claim 1, wherein a plurality of throughholes are formed on the heat slug.

14. A method of fabricating a semiconductor chip package, comprising:
preparing the semiconductor chip having a plurality of conductive bumps on a front surface of the semiconductor chip;
bonding a heat slug on a backside of the semiconductor chip using a solder film; and
attaching the semiconductor chip on a substrate such that the conductive bumps of the semiconductor chip contacts a plurality o bonding pads on the substrate.

15. The method of claim 14, further comprising filling a space between the semiconductor chip and the substrate.

16. A semiconductor chip package comprising:
a substrate having a plurality of bonding pads;
a semiconductor chip having a plurality of conductive bumps on a front side thereof, the conductive bumps contacting the bonding pads;
a heat slug bonded to a backside of the semiconductor chip, the heat slug comprising a top portion, side standing portions bent from the top portion, and side end portions bent again from the side standing portions; and
a solder film that bonds the heat slug to the backside of the semiconductor chip,
wherein the top portion of the heat slug contacts the conductive solder film and the side end portions of the heat slug are attached to the substrate by an adhesive.

17. The semiconductor chip package of claim 16, wherein the solder film has a size equal to or larger than a size of the semiconductor chip.

18. The semiconductor chip package of claim 16, wherein the heat slug is formed of a material selected from a group consisting of Cu, Al, and CuW.

19. The semiconductor chip package of claim 16, wherein the heat slug comprises an adhesion layer formed on a surface of the heat slug that contacts the solder film.

20. The semiconductor chip package of claim 16, wherein the heat slug is coated with an anodizing layer.
